(19) United States
(12) Patent Application Publication
(10) Pub. No.: US 2010/0032186 A1
(43) Pub. Date: Feb. 11, 2010

(54) TRANSPARENT ELECTRODE FOR DISPLAY DEVICE AND MANUFACTURING METHOD THEREOF

(75) Inventors: Hiroshi Gotou, Hyogo (JP); Hiroyuki Okuno, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA KOBE SEIKO SHO (KOBE STEEL, LTD.), KOBE-SHI (JP)

(21) Appl. No.: 12/528,008

(22) PCT Filed: Feb. 25, 2008
(86) PCT No.: PCT/JP08/53212

§ 371 Date: Aug. 20, 2009

(30) Foreign Application Priority Data
Mar. 1, 2007 (JP) 2007-051858

(51) Int. Cl. H01B 5/00; H05K 1/09; C23C 14/34

(52) U.S. Cl. 174/126.2; 174/126.1; 204/192.15

(57) ABSTRACT

The present invention relates to a transparent electrode for a display device which includes a first transparent conductive film containing nitrogen, and a second transparent conductive film not containing nitrogen, wherein the first transparent conductive film is in contact with an aluminum alloy film. In accordance with the present invention, there is obtained a transparent electrode for a display device which is capable of, even when a barrier metal layer to be generally provided between an aluminum alloy film and the transparent electrode is omitted, controlling the variance small while keeping the low contact resistance, and further which is also excellent in light transmission characteristics.

### TECHNICAL FIELD

The present invention relates to a transparent electrode for a display device, and a manufacturing method thereof. More particularly, it relates to an improved technology of a transparent electrode for a display device in which the transparent conductive film forming the transparent electrode is in direct contact with an aluminum alloy film for use in source-drain electrodes, reflection electrodes, and the like.

### BACKGROUND ART

In recent years, with a progress of the development of liquid crystal displays, liquid panels with a screen size of more than 100 inches have come to be manufactured. The 30- to 40-inch diagonal liquid crystal display-mounted TVs have also been mass produced, which has created a strong demand for reduction of manufacturing cost thereof. Of liquid crystal displays for TVs and personal computers, those of an active panel type having a structure in which one transistor is disposed for each pixel have been the mainstream because of high operation speed thereof.

FIG. 3 shows one example of a schematic cross section of a conventional active panel type liquid crystal display device. In FIG. 3, the device includes a TFT array substrate 2 on which TFT's 1 (thin film transistors) are disposed in a grid, an opposing substrate 3 disposed opposite the TFT array substrate 2, and a liquid crystal layer 4 functioning as an optical modulation layer, disposed between the TFT array substrate 2 and the opposing substrate 3. The TFT array substrate 2 includes TFT's 1 disposed on the insulating substrate such as glass, a transparent electrode 5, wiring parts including a scanning line and a signal line (not shown), and an insulating film (not shown) between the wiring parts. The opposing substrate 3 includes a common electrode 6 formed over the entire surface, a color filter 7 disposed at a position opposite the transparent electrode 5, a light shield film 8 disposed at a position opposite the TFT's 1 and the wiring parts on the TFT array substrate 2, and the like. On the outer sides of the insulating substrates forming the TFT array substrate 2 and the opposing substrate 3, polarizing plates 9 are disposed. Whereas, on the opposing substrate 3, there is disposed an alignment film 10 for aligning liquid crystal molecules contained in the liquid crystal layer 4 in a prescribed orientation.

With the liquid crystal panel shown in FIG. 3, the alignment of the liquid crystal molecules contained in the liquid crystal layer 4 is controlled by the difference in voltage between the opposing electrode 3 and the transparent electrode 5. Thus, the light passing through the liquid crystal layer 4 between the TFT array substrate 2 and the opposing substrate 3 is modulated. As a result, the amount of light passing through the color filter 7 is controlled, so that color pixels with contrast are displayed. The TFT array substrate 2 is driven by a driver IC 12 and a control IC 13 via a TAB tape 11 extracted outside the TFT array.

FIG. 4 is an enlarged cross sectional view of the vicinity of the TFT 1 shown in FIG. 3. In FIG. 4, in the TFT array substrate 2, a source region 14 and a drain region 15 including a low resistance n type semiconductor polysilicon (n⁺ poly-Si), and polysilicon (poly-Si) which is a channel layer 16 are formed, and a gate electrode 18 is formed via a gate insulating layer 17. The source region 14 and the drain region 15 are connected to a source electrode 19 and a drain electrode 20, respectively. The drain electrode 20 is connected to the transparent electrode 5 formed of ITO (Indium-Tin-Oxide). The transparent electrode 5 is connected to the drain electrode 20 via a barrier metal layer 21a formed of a refractory metal such as Mo, Cr, Ti, or W. Whereas, the transparent electrode 5 is connected to a reflection electrode 22 via a barrier metal layer 21b formed of a refractory metal such as Mo.

Provision of the reflection electrode 22 promotes aligning of the liquid crystal molecules immediately on the TFT 1, and improves the brightness of the liquid crystal pixels by reflection of a transmitted light by the reflection electrode 22, and further produces an effect of enlarging the narrow viewing angle which is the weak point of the liquid crystal display.

The source-drain wires to be electrically connected to the source electrode 19-drain electrode 20, and the signal line to be electrically connected to the transparent electrode 5 (signal line for a transparent electrode) is formed of a thin film of pure Al or an aluminum alloy such as Al—Nd (which will be hereinafter referred to as an aluminum type alloy collectively) for the reasons of low electric resistivity, easy processing, and the like.

Then, the operation principle of the liquid crystal display device will be described. When a voltage (gate voltage) is applied to the gate electrode 18 of the TFT 1, the TFT 1 is rendered in an ON state. Thus, by the driving voltage previously applied to the source electrode 19 and the drain electrode 20, an electric current flows from the source electrode 19 through the channel layer 16 to the drain electrode 20. As a result, a voltage is applied to the transparent electrode 5 to cause a difference in electric potential with the common electrode 6 shown in FIG. 3. Accordingly, the liquid crystal molecules contained in the liquid crystal layer 4 are aligned, so that optical modulation is caused.

In FIG. 4, the barrier metal layers 21a and 21b formed of a refractory metal such as Mo are provided between the transparent electrode 5 and the drain electrode 20, and between the transparent electrode 5 and the reflection electrode 22, respectively. The reason for this is that a direct connection between the drain electrode 20 and the reflection electrode 22 and the transparent electrode 5 results in an increase in contact resistance, which degrades the display quality of the screen. Al for use as a wiring material for a transparent electrode is very susceptible to oxidation. For this reason, by oxygen formed in the process of deposition of a liquid crystal panel, oxygen to be added during deposition, or the like, an insulation layer of an Al oxide is formed at the interface between the Al type alloy thin film and the transparent electrode. Further, the ITO [oxide of indium (In) and tin (Sn), Indium Tin Oxide] or IZO [oxide of indium (In) and zinc (Zn), Indium Zinc Oxide] generally used as a transparent electrode material is a conductive metal oxide. However, when the Al oxide layer is formed as described above, electric ohmic connection cannot be carried out.

However, in order to form the barrier metal layer, a deposition device for barrier metal formation becomes additionally necessary in addition to the deposition device for Al type alloy wiring formation. Specifically, a deposition device including deposition chambers for barrier metal formation respectively additionally mounted therein (typically, a cluster tool in which a plurality of deposition chambers are connected to a transfer chamber) must be used, which entails an increase in manufacturing cost and reduction of productivity.

Whereas, the metal for use as the barrier metal layer and an aluminum type alloy are different in processing rate during the processing step such as wet etching using a chemical solution. For this reason, it becomes very difficult to control the lateral processing dimension in the processing step. Therefore, formation of the barrier layer entails complication of the step not only from the viewpoint in deposition but also from the viewpoint of processing, which entails an increase in manufacturing cost and reduction of productivity.

Under such circumstances, there are proposed direct contact technologies capable of direct contact between an aluminum type alloy film and a transparent electrode (Patent Document 1 to Patent Document 3).

Out of these, in Patent Document 1, there is disclosed an aluminum alloy thin film comprising at least one alloy element selected from a group consisting of Au, Ag, Zn, Cu, Ni, Sr, Sm, Ge, and Bi in a total content of 0.1 to 6 at % as a material which can be directly connected with a transparent electrode.

In Patent Document 2, there is disclosed an aluminum alloy multilayer film in which a nitrogen-containing aluminum alloy film (second layer) is formed on top of an aluminum alloy film (first layer) containing at least Ni in an amount of 0.1 to 6 at % as an alloy component as a material in which the aluminum alloy film can be directly connected with a transparent electrode, and has a chemical resistance, particularly, an excellent resistance to an alkaline developer or a removing solution.

In Patent Document 3, there is disclosed, as another material in which an aluminum alloy film can be directly connected to a transparent electrode, a material in which at the interface between an aluminum alloy film comprising at least one alloy element selected from a group consisting of Au, Ag, Zn, Cu, Ni, Sr, Sm, Ge, and Bi in a total content of 0.1 to 6 at %, and the transparent electrode, an oxide film of the aluminum alloy is formed, with the thickness and the oxygen content of the oxide film properly controlled.

On the other hand, although not related to the direct contact technology, in Patent Document 4, there is disclosed a transparent electrode having a nitrogen-containing transparent conductive film.

Patent Document 4 relates to the improved technology of the problem in H₂ cleaning to be performed for the purpose of removing impurities after pixel electrode formation (the metal components of ITO forming pixel electrodes are reduced, so that metals are precipitated on the surface, resulting in reduction of the transmittance of pixels). Herein, there is disclosed a pixel electrode having a conductive film containing nitrogen on the surface thereof in order to solve the foregoing problem. Specifically, there are disclosed a pixel electrode comprising a nitrogen-containing transparent conductive film (monolayer film), and a pixel electrode comprising a lamination film having a nitrogen-containing transparent conductive film on a transparent conductive film.

[Patent Document 1] Japanese patent laid-open No. 2004-214606

[Patent Document 2] Japanese patent laid-open No. 2005-303003

[Patent Document 3] Japanese patent laid-open No. 2006-23388

[Patent Document 4] Japanese patent laid-open No. 2006-133769

### DISCLOSURE OF THE INVENTION

The present inventors repeatedly conducted a study with the aim of further improvement of characteristics of the direct contact-related technologies as described in the Patent Documents 1 to 3. Specifically, in the Patent Documents, reduction of the contact resistance, and the like are achieved by controlling the amount of the alloy elements added in Al to 0.1 to 6 at %. However, in the actual operation, there is a strong demand for provision of a technology capable of obtaining the foregoing characteristics even when the amount of alloy elements to be added is minimized (e.g., to about 0.1 to 2 at %), and capable of manufacturing a high-performance display device with stability and with good reproducibility. To that end, the following are necessary: (a) while the contact resistance is being kept at a desirable low level, the variance (degree of variation of data) is minimized; and (b) the visible light transmission characteristics are not deteriorated.

The present invention was completed in view of the foregoing circumstances. It is an object thereof to provide a transparent electrode for a display device which is capable of, even when a barrier metal layer to be generally provided between an aluminum alloy film and the transparent electrode is omitted, controlling the variance (variation) small while keeping the low contact resistance, and further which is also excellent in light transmission characteristics, and a manufacturing method thereof.

A transparent electrode for a display device of the present invention, which could solve the foregoing problem, has the gist in the following: it includes a first transparent conductive film containing nitrogen, and a second transparent conductive film not containing nitrogen, wherein the first transparent conductive film is in contact with an aluminum alloy film.

In a preferred embodiment, the ratio of nitrogen contained in the first transparent conductive film is 1.5 at % or more and 5 at % or less.

In a preferred embodiment, the thickness (T1) of the first transparent conductive film falls within the range of 1 nm or more and 25 nm or less.

In a preferred embodiment, the ratio (T1/T2) of the thickness (T1) of the first transparent conductive film and the thickness (T2) of the second transparent conductive film is 1 or less.

In a preferred embodiment, the aluminum alloy film contains at least one element selected from the group consisting of Ni, Ag, Zn, Cu, and Ge as an alloy element in an amount within the range of 0.1 at % or more and 6 at % or less, and further preferably 0.1 at % or more and 2 at % or less.

In a preferred embodiment, the aluminum alloy film further contains at least one element selected from the group consisting of La, Gd, Dy, Mg, Nd, Y, Fe, and Co as an alloy element in an amount within the range of 0.1 at % or more and 2 at % or less.

In a preferred embodiment, the aluminum alloy film is for use in source-drain electrodes or a reflection electrode.

A display device of the present invention includes the transparent electrode according to any of the following items.

A method for manufacturing a transparent electrode for a display device in accordance with the present invention, which could solve the foregoing problem, has the gist in the following: it includes: a first step of depositing a first transparent conductive film containing nitrogen on an aluminum alloy film with a sputtering process; and a second step of depositing a second transparent conductive film not containing nitrogen on the first transparent conductive film containing nitrogen with a sputtering process, wherein the first step is performed by using a mixed gas of an inert gas and a nitrogen gas, and controlling the ratio (F2/F1) of the flow rate F2 of a nitrogen gas to the flow rate F1 of the mixed gas within the range of 0.05 or more and 0.5 or less.

The present invention is configured as described above. Therefore, it is possible to obtain a transparent electrode for a display device having a low contact resistance with less variance (variation), and a high transmittance, even when the transparent electrode is in direct contact with the aluminum alloy film.

The effect by the present invention is exerted when the amount of alloy components such as Ni contained in the aluminum alloy film is 6 at % or less, and becomes remarkable when the amount is as especially small as 2 at % or less.

Therefore, by the use of the transparent electrode for a display device of the present invention, it is possible to manufacture a high-performance display device with stability and with good reproducibility.

### BRIEF DESCRIPTION OF THE DRAWINGS

FIG. 1(a) is a schematic cross sectional view schematically showing a part of a TFT substrate including a conventional transparent electrode disposed therein, and FIG. 1(b) is a schematic cross sectional view schematically showing a part of a TFT substrate including a transparent electrode of the present invention disposed therein;

FIG. 2 are each a step cross sectional view of a display device in an embodiment of the present invention;

FIG. 3 is a schematic cross sectional view of a conventional display device;

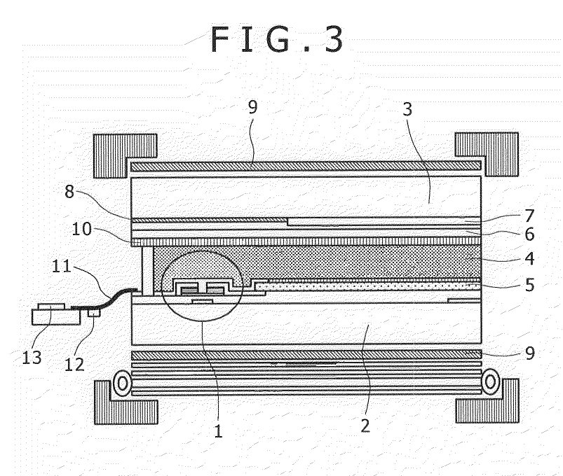

FIG. 4 is a cross sectional view of an essential part of the conventional display device;

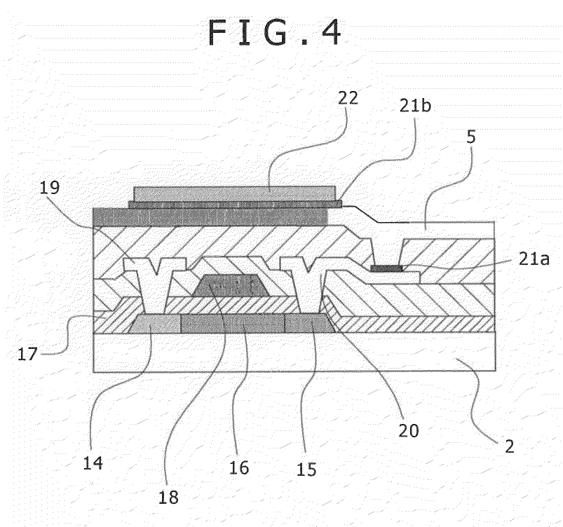

FIG. 5 is a view showing a Kelvin pattern used for the measurement of the contact resistance between an aluminum alloy film and the transparent electrode;

FIG. 6 is a graph showing the relationship between the gas flow rate ratio (F2/F1) and the contact resistivity in Example 1;

FIG. 7 is a graph showing the relationship between the nitrogen content in a nitrogen-containing ITO film (ITO: N) and the contact resistivity in Example 1;

FIG. 8 is a graph showing the correlation between the gas flow rate ratio (F2/F1) and the nitrogen content in the nitrogen-containing ITO film (ITO: N); and

FIG. 9 is a graph showing the relationship between the ratio (T1/T2) of thicknesses of a first transparent conductive film and a second transparent conductive film, and the transmittance at each wavelength in Example 3.

### EXPLANATION OF REFERENCE SIGNS AND NUMERALS

1 TFT

2 TFT array substrate

3 opposing substrate

4 Liquid crystal layer

5 Transparent electrode

6 Common electrode

7 Color filter

8 Light shielding film

9 Polarizing plate

10 Alignment film

11 TAB tape

12 Driver IC

13 Control IC

14 Source region

15 Drain region

16 Channel layer

17 Gate insulating film

18 Gate electrode

19 Source electrode

20 Drain electrode

21a, 21b Barrier metal layer

22 Reflection electrode

25 Scanning line

26 Gate electrode

27 Gate insulating film

28 Source electrode

29 Drain electrode

30 Silicon nitride film

32 Contact hole

33 Active semiconductor layer

55 Hydrogenated amorphous silicon film

56 n⁺ type hydrogenated amorphous silicon film

60, 70 Transparent electrode

61 First transparent conductive film containing nitrogen

62 Second transparent conductive film not containing nitrogen

63 Aluminum alloy film

64 Transparent conductive film

65 Contact hole

67 Insulating film

### BEST MODE FOR CARRYING OUT THE INVENTION

The present inventors have pursued a study in order to provide a technology capable of manufacturing a high-performance display device with stability and with good reproducibility even when the amount of alloy elements added in aluminum is controlled low (to generally about 2 at % or less) in the direct contact technologies (technologies enabling reduction of the contact resistance even when the transparent electrode is in direct contact with the aluminum alloy film) disclosed in the foregoing Patent Document 1 to Patent Document 3. As a result, it has been proved that reduction of the amount of alloy elements added in aluminum results in an increase in variance of the contact resistance. This problem has not been particularly recognized in the conventional direct contact technologies. Thus, the present inventors have further pursued a study mainly based on the viewpoint of “reducing the variance of the contact resistance”. Specifically, they pursued a study on the technology capable of controlling the variance of the contact resistance small based on the premise that the low contact resistance and the high transmittance required of a transparent electrode for a display device are kept as they are from the viewpoint of improvement of the transparent electrode for a display device. As a result, they found the following: the transparent electrode for a display device is configured to be a lamination thin film including a first oxide transparent conductive film (Transparent Conductive Oxide; TCO) containing nitrogen, and a second transparent conductive film not containing nitrogen, and the lamination thin film is configured such that the first transparent conductive oxide film is in contact with an aluminum alloy film. Then, the intended purpose is achieved. Thus, the present invention was completed.

Below, for convenience of description, the second transparent conductive film not containing nitrogen may be simply referred to as a “no nitrogen-containing transparent conductive film” or “TCO”. In contrast, the first transparent conductive film containing nitrogen may be simply referred to as a “nitrogen-containing transparent conductive film” or “TCO: N”. A conventional typical transparent electrode for a display device includes only a transparent conductive film (TCO) as with ITO or IZO.

In this description, the “transparent electrode for a display device” includes not only the transparent electrode (typically transparent pixel electrode) itself for use in a display device, but also a wire (signal line) to be electrically connected to the transparent electrode. Below, for convenience of description, the “transparent electrode for a display device” may be simply referred to as a “transparent electrode”.

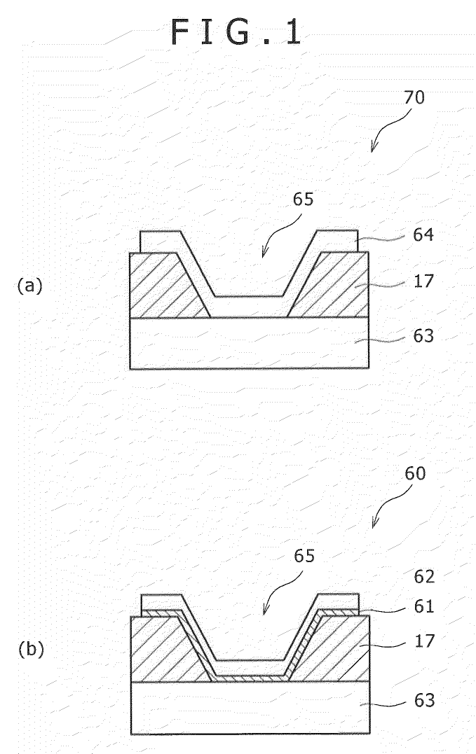

Below, with reference to FIG. 1, an embodiment of the transparent electrode in accordance with the present invention will be described. FIG. 1(b) is a schematic cross sectional view schematically showing a part of a TFT substrate including the transparent electrode of the present invention disposed therein. FIG. 1(a) is a schematic cross sectional view schematically showing a part of a TFT substrate including a conventional transparent electrode disclosed in Patent Document 1 to Patent Document 3.

As shown in FIG. 1(b), a transparent electrode 60 of the present invention includes a first transparent conductive film (TCO: N) 61 containing nitrogen, and a second transparent conductive film not containing nitrogen (TCO) 62. The first transparent conductive film 61 is in direct contact with an aluminum alloy film 63. Thus, the transparent electrode 60 of the present invention has the first transparent conductive film containing nitrogen (TCO: N) 61 between the second transparent conductive film not containing nitrogen (TCO) 62 and the aluminum alloy film 63. In this point, it is different from a conventional transparent electrode 70 which does not have a first transparent conductive film (TCO: N) 61, and in which a transparent conductive film (TCO) 64 and an aluminum alloy film 63 are in direct contact with each other.

As in the present invention, by adopting a lamination structure of second transparent conductive film (TCO)/first transparent conductive film (TCO: N)/aluminum alloy film, it is possible to suppress the variance of the contact resistance while keeping the low contact resistance even when the transparent electrode is in direct contact with the aluminum alloy film, and further, it is also possible to ensure a high transmittance. The reason (mechanism) for this is specifically unclear, but can be inferred as follows: the first transparent conductive film (TCO: N) becomes a so-called barrier layer, so that transfer of oxygen from the second transparent conductive film (TCO) to the aluminum alloy film is prevented; this prevents oxidation of the aluminum alloy film; as a result, reduction of the second transparent conductive film (TCO) is effectively prevented. In contrast, conceivably, as in the related art, when the transparent conductive film and the aluminum alloy film are in direct contact with each other, an oxide film is formed at the aluminum alloy film surface due to oxygen excessively contained in the transparent conductive film. Accordingly, desired characteristics cannot be ensured.

The barrier effect (oxygen diffusion preventing effect, or the like) by the first transparent conductive film (TCO: N) is effectively exerted especially when the amount of alloy elements contained in the aluminum alloy film is as relatively small as about 2 at % or less. This is due to the following: when the amount of alloy elements exceeds about 2 at %, the alloy elements themselves can exert the same barrier effect as that of the first transparent conductive film (TCO: N); for this reason, a problem such as an increase in variance of the contact resistance is not noticeably observed. Therefore, when the amount of alloy elements contained in the aluminum alloy film exceeds 2 at %, the constitution of the present invention is not necessarily required to be adopted. However, it is naturally understood that, with the aim of further improving the characteristics, the constitution of the present invention may be adopted even when the amount of alloy elements contained in the aluminum alloy film is about 2 to 6 at %.

The barrier effect by the first transparent conductive film (TCO: N) can be obtained by interposing the first transparent conductive film between the aluminum alloy film and the second transparent conductive film (TCO). However, with the aim of further suppressing the variance of the contact resistance, the following are effective (details thereof will be described later): (a) the nitrogen content in the first transparent conductive film is properly controlled; and (b) the thickness (T1) of the first transparent conductive film, and the ratio (T1/T2) of the thickness (T1) of the first transparent conductive film and the thickness (T2) of the second transparent conductive film are properly controlled.

Incidentally, in Patent Document 4 described above, a transparent electrode including a transparent conductive film containing nitrogen is also disclosed, but is different from the transparent electrode of the present invention in the following points.

First, both are different from each other in solving problems. Patent Document 4 relates to a technology of preventing reduction of the transmittance of pixels due to reduction of metal components such as ITO in a sintering step (H₂ annealing step for restoring defects of the semiconductor interface layer) to be performed after pixel electrode formation, particularly with the aim of preventing reduction of the ITO surface layer, and does not relate to a direct contact technology of directly connecting the aluminum alloy film with the transparent electrode as in the present invention. In Patent Document 4, the data line or the drain electrode includes a lower film (barrier layer of Mo, Mo alloy, Cr, or the like), and an upper film (Al or Al alloy film). In Patent Document 4, there is no idea at all of a direct contact technology in which a barrier metal layer is omitted, so that the aluminum alloy film and the transparent electrode are in direct contact with each other.

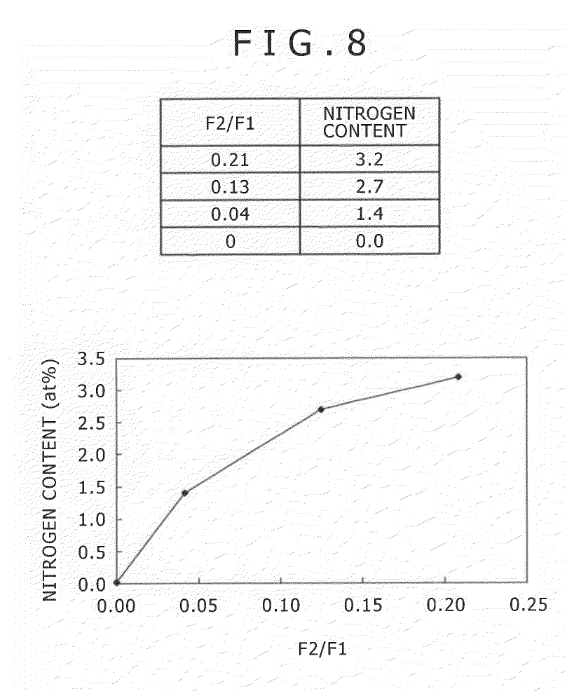

Further, both are also different from each other in configuration. Both are in agreement with each other in that either has a transparent conductive film containing nitrogen (TCO: N). However, the nitrogen-containing transparent conductive film (TCO: N) is disposed between the no nitrogen-containing transparent conductive film (TCO) and the aluminum alloy film in the present invention. In contrast, in Patent Document 4, it is disposed on the no nitrogen-containing transparent conductive film (TCO). Thus, both are different from each other in disposing site. In Patent Document 4, in order to prevent reduction of metals such as ITO in the H₂ annealing step, the nitrogen-containing transparent conductive film (TCO: N) is required to be disposed on the outermost surface. In contrast, in the present invention, in order to provide a transparent electrode having a low contact resistance with less variations and high transmittance even when a barrier metal layer is omitted, the nitrogen-containing transparent conductive film (TCO: N) must be disposed between the no nitrogen-containing transparent conductive film (TCO) and the aluminum alloy film. Further, in Patent Document 4, there is also disclosed a transparent electrode including only a nitrogen-containing transparent conductive film (TCO: N). However, it has been experimentally confirmed that, in this case, the contact resistivity is good, but the transmittance is remarkably reduced (see FIG. 8 of Example 3 described later).

The “containing nitrogen” in “first transparent conductive film containing nitrogen” characterizing the present invention means that a part or the whole of the transparent conductive film has been nitrided. Specifically, the first transparent conductive film (TCO: N) 61 preferably contains nitrogen in an amount within the range of 1.5 at % or more and 5 at % or less in the transparent conductive film. Herein, the “nitrogen content” means the nitrogen concentration at the interface (the portion at which the nitrogen content is highest) between the aluminum alloy film 63 and the first transparent conductive film (TCO: N) 61. As specifically described later, the first transparent conductive film 61 is formed by deposition on the aluminum alloy film 63 by a sputtering process (reactive sputtering process) using a mixed gas of an inert gas such as an Ar gas and a nitrogen gas. Therefore, the first transparent conductive film 61 has a concentration gradient at which the nitrogen content decreases stepwise from the aluminum alloy film 63 side toward the second transparent conductive film 62. There is a nitrogen-containing layer at the interface between the aluminum alloy film 63 and the first transparent conductive film 61. On the other hand, the nitrogen-containing layer is substantially 0 (zero) on the upper layer side from the interface between the first transparent conductive film 61 and the second transparent conductive film 62. The experiments by the present inventors proved that desirable characteristics are effectively exerted when the maximum concentration of nitrogen in the Al alloy film interface is controlled within the range of, preferably, 1.5 at % or more to 5 at % or less. When the content of nitrogen in the first transparent conductive film is less than 1.5 at %, the variance of the contact resistance becomes large. From the viewpoints of reduction of the contact resistance and control of the variance, the nitrogen content is more desirably higher, and is preferably, for example, 2 at % or more. The upper limit thereof is set at 5 at % in view of the transmittance, the sheet resistance, and the like. The content of nitrogen in the first transparent conductive film is more preferably 4 at % or less, and further preferably 3 at % or less.

The content of nitrogen in the first transparent conductive film can be adjusted by, for example, controlling the flow rate ratio of the mixed gas (specifically, the ratio of the flow rate F2 of a nitrogen gas to the flow rate F1 of the mixed gas of an inert gas and a nitrogen gas, F2/F1), and performing sputtering as in Examples described later. Incidentally, even when the sputtering conditions are the same, the amount of nitrogen to be taken into the transparent conductive film differs according to the type of the transparent conductive film. Therefore, in actuality, it is essential only that the sputtering conditions are appropriately set according to the type of the transparent conductive film and the like.

The content of nitrogen in the first transparent conductive film 61 can be observed by means of an XPS (X-ray Photoelectron Spectrometer).

The thickness (T1) of the first transparent conductive film 61 (TCO: N)is preferably within the range of 1 nm or more and 25 nm or less. When T1 is less than 1 nm, the barrier effect by the first transparent conductive film 61 is not effectively exerted, so that the desirable contact resistance variation reducing effect cannot be obtained. On the other hand, when T1 exceeds 25 nm, the visible light transmittance is reduced, and in addition, problems such as peeling off of the first transparent conductive film occur. In consideration of the balance between the contact resistance and the transmittance, T1 is preferably within the range of 2 nm or more and 15 nm or less, and more preferably is within the range of 5 nm or more and 10 nm or less.

Further, preferably, the ratio (T1/T2) of the thickness (T1) of the first transparent conductive film (TCO: N) 61 and the thickness (T2) of the second transparent conductive film (TCO) 62 is 1 or less, namely T1 is smaller than T2 (T1≦T2). As described above, the first transparent conductive film (TCO: N) 61 mainly has an effect of reducing variation of the contact resistance. In order to ensure the desirable contact resistance characteristics, it is useful. However, too large thickness results in reduction of the transmittance. The experimental results of the present inventors have proved the following: when the ratio (T1/T2) exceeds 1 (i.e., T1>T2), the visible light transmittance is reduced (see Examples described later). In consideration of the balance between the contact resistance and the transmittance, the ratio (T1/T2) is preferably 0.25 or more and 1 or less, and more preferably 0.5 or more and 0.8 or less.

Up to this point, the first transparent conductive film characterizing the present invention was described.

As repeatedly described, the transparent electrode of the present invention is characterized by including, in the conventional transparent electrode including only a transparent conductive film (monolayer film), the “first transparent conductive film containing nitrogen” resulting from nitriding of a part thereof between it and the aluminum alloy film. Therefore, the type of the transparent conductive film in the “second transparent conductive film not containing nitrogen” (TCO) has no particular restriction, and those generally used in the related art can be used. Further, the aluminum alloy films also have no particular restriction so long as they are those disclosed in the direct contact technologies typified by Patent Document 1 to Patent Document 3 described above.

The second transparent conductive film 62 includes only a transparent conductive film, and substantially does not contain nitrogen. Herein, the “substantially does not contain” means being capable of allowing nitrogen in an amount at a level capable of being inevitably contained in the formation process of the thin film described later. Therefore, the content of nitrogen is not necessarily 0 at %, and nitrogen at a level not inhibiting the effect of the present invention, for example, in an amount of about 200 atom-ppm may be contained.

The transparent conductive film forming the first transparent conductive film 61 and the second transparent conductive film 62 has no particular restriction. A film for use in a conventional pixel electrode can be used. Typically, mention may be made of ITO, IZO, or the like. Other than this, there are exemplified films of IGO, IWO, ZnO, TiO₂, and the like, a film obtained by adding Al or Ga to ZnO, and the like. The first transparent conductive film 61 and the second transparent conductive film 62 may be formed of the same transparent conductive film, or may be different. However, in view of the productivity, and the like, both are preferably formed of the same transparent conductive film.

As the aluminum alloys for use in the aluminum alloy film, for example, those with the compositions described in Patent Document 1 to Patent Document 3 described above are preferably used. Use of such aluminum alloys can prevent reduction of the TFT characteristics due to pin holes or the like, and can provide wiring or electrodes capable of being in direct contact with the transparent electrode.

Specifically, as the aluminum alloys, those having the following compositions (1) and (2) are preferable.

(1) Al-α alloy containing at least one of elements belonging to the group α in an amount within the range of 0.1 at % or more and 6 at % or less

Herein, the group α includes Ni, Ag, Zn, Cu, and Ge. The elements belonging to the group α maybe added alone, or may be used in combination of two or more thereof. When two or more elements are added, it is essential only that the total content of respective elements satisfy the foregoing range.

The elements belonging to the group α are useful for reducing the electric resistivity. When these elements are used alone or in combination to be added in Al in an amount within the foregoing range, a low electric resistance region containing at least a part of the elements belonging to α (α-containing precipitate or α-containing concentrated layer) is formed at the contact interface between the aluminum type alloy thin film and the transparent electrode (strictly, the first transparent conductive film) at a relatively low heat treatment temperature. Therefore, for example, the electric resistivity upon a heat treatment at 250° C. for 30 minutes can be reduced generally 7 μΩ·cm or less.

Out of the elements, Ni is particularly excellent in effect of reducing the electric resistivity and heat resistance. Therefore, an Al—Ni alloy containing at least Ni is preferably used.

When the elements belonging to the group α is in an amount of less than 0.1 at %, formation of the desirable α-containing concentrated layer is insufficient. Thus, the contact resistance cannot be controlled sufficiently low. However, when the content of elements belonging to the group α exceeds 6 at %, the electric resistivity of the Al type alloy thin film itself becomes high, and the response speed of pixels becomes slow. Accordingly, the power consumption increases, and the quality as a display is degraded, so that the display becomes unavailable for practical use. The preferred lower limit value of the content of elements belonging to the group α is 0.5 at %, and the preferred upper limit value thereof is 5 at %, and further preferably 2 at %.

(2) Al-α-β alloy containing at least one of elements belonging to the group α in an amount within the range of 0.1 at % or more and 6 at % or less, and containing at least one of elements belonging to the group β in an amount within the range of 0.1 at % or more and 2 at % or less

The Al-α-β alloy is a ternary alloy containing elements belonging to the group α, and further containing elements belonging to the group β as a third component. Herein, the group β includes La, Gd, Dy, Mg, Nd, Y, Fe, and Co. The elements belonging to the group β may be added alone, or may be used in combination of two or more thereof. When two or more elements are added, it is essential only that the total content of respective elements satisfy the foregoing range.

The elements belonging to the group β are useful for improvement of the heat resistance or the corrosion resistance. Further, when the amount of the elements added falls within the range of 0.1 to 2 at %, an adverse effect by addition of the elements is not observed, and it has also been confirmed that there is exerted an excellent effect comparable to that upon use of the Al-α alloy containing elements belonging to the group α. This is due to the following. Each element belonging to the group β is larger in atom radius than an aluminum atom. Even when the element is added, a sufficient space for a nitrogen atom to be taken into the transparent conductive film is ensured during the deposition process. Therefore, the desired nitrogen-containing first transparent conductive film (TCO: N) can be deposited with ease.

The preferred lower limit value of the content of elements belonging to the group β is 0.1 at %, and the preferred upper limit value is 2 at %. When the content of elements belonging to the group β is less than 0.1 at %, the effect of improving the heat resistance or the corrosion resistance is not effectively exerted. On the other hand, when the content exceeds 2 at %, the electric resistivity of wiring increases. The preferred lower limit value of the content of elements belonging to the group β is 0.1 at %, and further preferably 0.2 at %. Whereas, the preferred upper limit value of the content of elements belonging to the group β is 2 at %, and further preferably 0.6 at %.

In this description, the “substrate” has no restriction so long as it can be used as a TFT substrate. Typically, a glass substrate, a quartz substrate, a silicon substrate, a plastic substrate, a metal substrate, a flexible substrate, or the like can be used. The flexible substrate is a film-like substrate including PET, PES, PEN, acrylic, or the like. This can allow reduction in weight of a semiconductor device.

Then, a description will be given to the manufacturing steps of the transparent electrode in accordance with the embodiments.

A method for manufacturing a transparent electrode of this embodiment includes a first step of depositing a first transparent conductive film containing nitrogen on an aluminum alloy film by a sputtering process, and a second step of depositing a second transparent conductive film not containing nitrogen on the first transparent conductive film containing nitrogen by a sputtering process, characterized in that the first step is performed using a mixed gas of an inert gas and a nitrogen gas, and controlling the ratio (F2/F1) of the flow rate F2 of a nitrogen gas to the flow rate F1 of the mixed gas within the range of 0.05 or more and 0.5 or less.

Below, respective steps will be described sequentially.

(First Step)

The first transparent conductive film containing nitrogen characterizing the present invention is deposited by a reactive sputtering process using a mixed gas of an inert gas and nitrogen. Specifically, sputtering is carried out using a mixed gas of an inert gas of Ar, Ne, or the like and a N₂ gas. The nitrogen content in the first transparent conductive film can be controlled by changing the ratio (F2/F1) of the flow rate F1 of the mixed gas and the flow rate F2 of a nitrogen gas. When the ratio (F2/F1) is adjusted within the range of, generally, 0.05 or more and 0.5 or less, the nitrogen content in the first transparent conductive film can be controlled within the range of, generally, 1.5 at % or more and 5 at % or less.

Other conditions have no particular restriction, but, for example, they are preferably controlled as follows.
Substrate temperature: room temperature to 150° C.
Attainable degree of vacuum: 1×10⁻⁵ Torr or less
Gas pressure during deposition: 1 to 30 mTorr
DC sputtering power density
   (DC sputtering power per unit area of target): 1 to 5 W/cm²

(Second Step)

Then, on the first transparent conductive film containing nitrogen formed in the foregoing manner, a second transparent conductive film not containing nitrogen is deposited by a sputtering process. The step of depositing the second transparent conductive film with a sputtering process may be performed in the same manner as with the first step, except that a mixed gas of an inert gas (typically an Ar gas) and O₂ (e.g., Ar:N₂=24:0.06) is used in place of the mixed gas of an inert gas and nitrogen in the first step. Specifically, reference may be made to, for example, the methods described in Patent Document 1 to Patent Document 3 described above.

The transparent electrode of the present invention is applicable to various display devices such as organic EL (Electro Luminescence) displays, LED elements or LED displays other than liquid crystal displays and liquid crystal display devices for projectors.

As the methods for manufacturing a TFT substrate including the transparent electrode of the present invention, generally used methods can be basically adopted, except that the transparent electrode is in a lamination structure of a first transparent conductive film containing nitrogen, and a second transparent conductive film not containing nitrogen, and is configured such that the first transparent conductive film is in contact with the aluminum alloy film.

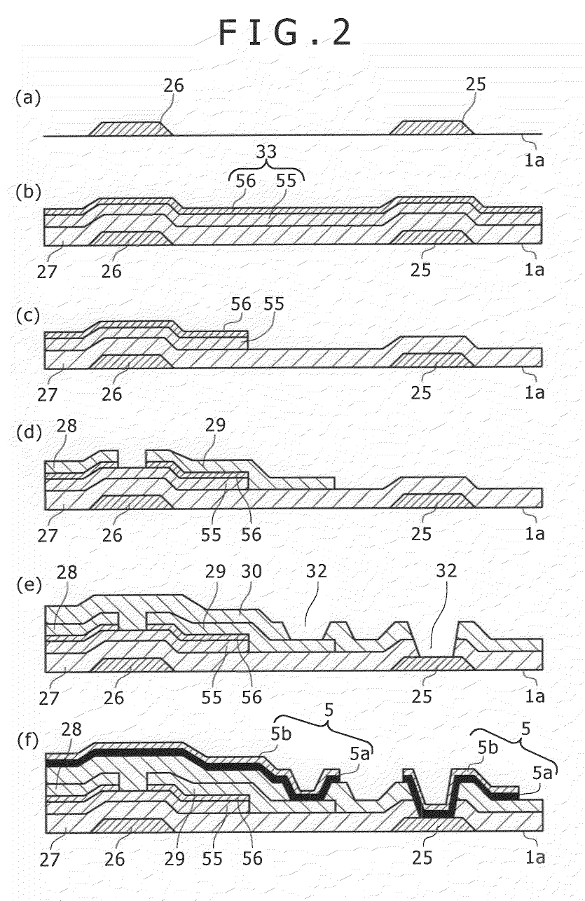

Below, with reference to FIG. 2, a description will be given to the method for manufacturing a TFT substrate including the transparent electrode of the present invention. Hereinafter, a step of providing the transparent electrode 5 of the present invention on the upper side of the aluminum alloy film forming the drain electrode 29 will be described. However, the present invention is not limited thereto. For example, it is also acceptable that the transparent electrode 5 of the present invention is disposed on the upper side of the aluminum alloy film forming the reflection electrode.

First, as shown in FIG. 2(a), an Al type alloy thin film with a thickness of about 250 nm is stacked on a glass substrate la by a sputtering process. The deposition temperature of sputtering is set at room temperature. By patterning the Al type alloy thin film, a gate electrode 26 and a scanning line 25 are formed. At this step, in the step shown in FIG. 2(b) described later, it is desirable that the circumference of the lamination thin film is etched in the form of a taper with an angle of about 30° to 60° so as to improve the coverage property of a gate insulating film 27.

Then, as shown in FIG. 2(b), with a process such as a plasma CVD process, a silicon nitride film (gate insulating film) 27 with a thickness of about 300 nm is formed. The deposition temperature of the plasma CVD process is set at about 350° C. Subsequently, for example, with a plasma CVD process, a•non-doped hydrogenated amorphous silicon film (a-Si—H) 55 with a thickness of about 200 nm and a phosphorus-doped n⁺ type hydrogenated amorphous silicon film (n⁺ a-Si—H) 56 with a thickness of about 80 nm are sequentially stacked on the silicon nitride film (gate insulating film) 27. Thus, an active semiconductor layer 33 serving as an active layer of the TFT is formed. The n⁺ type hydrogenated amorphous silicon film 56 is formed by, for example, performing a plasma CVD process added with a PH₃ gas at a prescribed partial pressure.

The active semiconductor layer 33 including the hydrogenated amorphous silicon film 55 and the n⁺ type hydrogenated amorphous silicon film 56 formed in this manner is patterned as shown in FIG. 2(c).

Then, with a sputtering process, an Al alloy film with a thickness of about 300 nm is formed. The deposition temperature of sputtering is set at room temperature. By patterning the Al alloy film, as shown in FIG. 2(d), a source electrode 28 and a drain electrode 29 integral with a signal line are formed. Further, with the source electrode 28 and the drain electrode 29 as a mask, the n⁺ type hydrogenated amorphous silicon film 56 is dry etched, and removed.

Then, as shown in FIG. 2(e), a silicon nitride film (protective film) 30 with a thickness of about 300 nm is formed with, for example, a plasma CVD device. Deposition at this step is performed at about 200° C. Then, a contact hole 32 is formed by performing dry etching or the like on the silicon nitride film 30.

Then, based on the foregoing method, a lamination film of a first layer 5a formed of a transparent conductive film containing nitrogen (ITO film obtained by adding 10 mass % tinoxide to indiumoxide), and a second layer 5b formed of the same transparent conductive film as described above is deposited. Then, patterning by wet etching is carried out to form a transparent electrode 5. As a result, a TFT substrate shown in FIG. 2(f) is completed. In order to establish an electric connection with the drain electrode 29, the first layer 5a formed of a transparent conductive film containing nitrogen is in mutual contact therewith. At this contact portion, a contact with low contact resistance can be obtained even when a barrier metal layer of Mo or the like as in the related art is not interposed between the transparent electrode and the drain electrode.

In the foregoing description, the example using an amorphous silicon film as an active semiconductor layer was taken. However, a polysilicon film may also be used. As the material for the transparent conductive film, other than the ITO film, an IZO film or the like can be used. Further, in the example of FIG. 2, there was shown the example in which the hydrogenated amorphous silicon film 55 which is an active semiconductor layer is formed on the upper side of the gate electrode 26. However, it may also be configured such that the active semiconductor layer is formed on the lower side of the gate electrode 26.

### Examples

Below, the present invention will be more specifically described by way of examples. However, it is naturally understood that the present invention is not limited by the following examples, and can be carried out with proper changes within the scope adaptable to the gist described above and later. All of these are intended to be embraced by the technical scope of the present invention

### Example 1

In this example, it will be verified that use of the transparent electrode of the present invention can control the contact resistivity low, and also the variance small. Specifically, there were examined changes in contact resistivity upon changing the nitrogen content in the nitrogen-containing transparent conductive film by using a test device shown in FIG. 1B, and changing the ratio (F2/F1) of the flow rate F2 of a nitrogen gas to the flow rate F1 of a mixed gas (Ar+N₂) of an inert gas (Ar) and a nitrogen gas within the range of 0 to 0.15. Herein, as the transparent conductive film, an ITO film was used, and as the aluminum alloy film, an Al-0.3 at % Ni-0.35 at % La alloy was used.

First, on a glass substrate, a 30 nm-thick Al-0.3 at % Ni-0.35 at % La alloy film was deposited by a sputtering process in the following manner.

Target material: a sputtering target of Al-0.3 at % Ni-0.35 at % La is used (size: diameter 100 mm×thickness 5 mm);

Sputtering device: “HSM-552” manufactured by SHIMADZU Corporation is used;

Sputtering conditions (DC magnetron sputtering process)

Attainable degree of vacuum: 3×10⁻⁶ Torr or less

Gas: Ar gas

Gas flow rate: 30 sccm

Sputtering power: DC 150 W

Distance between electrodes: 50 mm

Substrate temperature: room temperature

Glass substrate: #1737 manufactured by Corning, diameter 10 mm×thickness 0.7 mm

Then, with a plasma CVD process, a silicon nitride film (gate insulating film) with a thickness of about 300 nm was formed. The deposition temperature of the plasma CVD process was set at about 350° C.

Then, with a sputtering process, the ITO film containing nitrogen (first transparent conductive film, ITO: N) was deposited by a sputtering process. Specifically, sputtering was carried out under the foregoing sputtering conditions, except that the nitrogen content in the ITO film was changed within the range of 0 to 3.2 at % by changing the gas flow rate ratio (F2/F1) within the range of 0 to 0.15 using ITO obtained by adding 10 mass % tin oxide to indium oxide as a target material. Thus, a first transparent conductive film with a thickness of 10 nm was deposited.

Then, sputtering was carried out under the foregoing conditions, except that all the gases in the sputtering device were replaced with an Ar gas. Thus, an ITO film (second transparent conductive film) with a thickness of 40 nm was deposited.

Then, the contact resistivity of the aluminum alloy film and the transparent electrode was measured in the following manner.

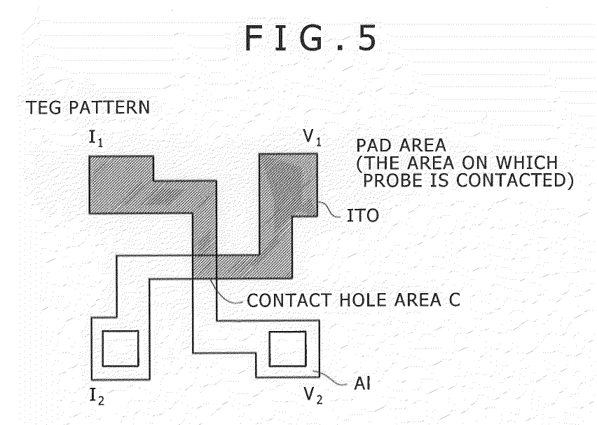

A Kelvin pattern (contact hole size: 10 μm square) shown in FIG. 5 was manufactured, and the four-terminal measurement (a method in which an electric current is caused to flow through the ITO-Al alloy, and at another terminal, the voltage drop across the ITO-Al alloy is measured) was performed. Namely, a current I was caused to flow across I₁-I₂ of FIG. 5, and the voltage V across V₁-V₂ was measured, thereby to determine the contact resistance R (Ω) of the contact hole area C as [R=(V₂−V₁)/I₂].

The same thirteen test devices as described above were manufactured, and the contact resistances were examined in the same manner as described above, and were converted to the contact resistivities (Ω·cm²). Then, the mean value thereof was calculated. Further, the variance of the contact resistivity was calculated based on the following expression:

Variance=1/nΣ_{λ=1}ⁿ(xi− x̅)² [Mathematical Expression 1]

where in the expression, xi denotes the individual contact resistivity, x̅ denotes the mean value, and n denotes the number.

In this example, the one with a mean of the contact resistivity of 2.7×10⁻⁴ Ω·cm² or less, and a variance of the contact resistivity within the range of 4×10⁻⁴ was evaluated as acceptable. The reference value of the contact resistivity is based on the contact resistivity of the ITO film not containing nitrogen and the Al alloy thin film (i.e., the contact resistivity when F2=0).

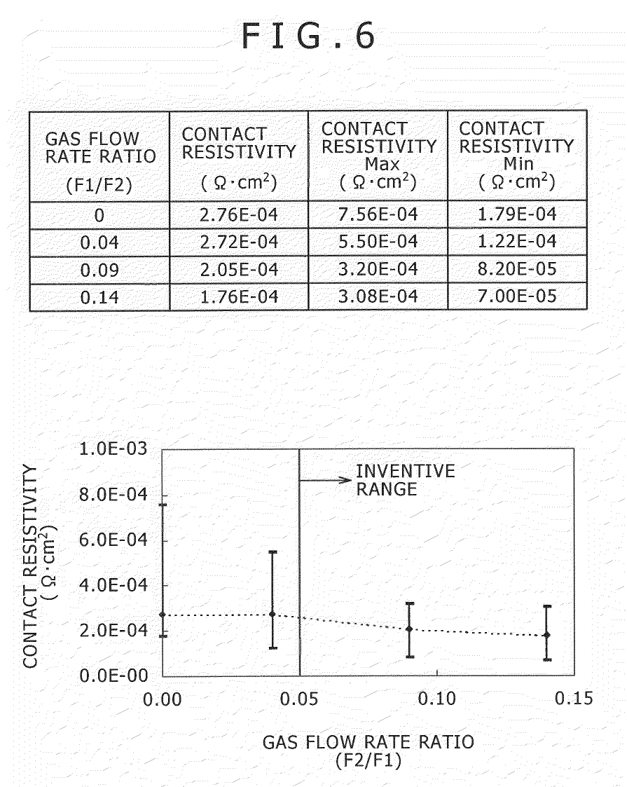

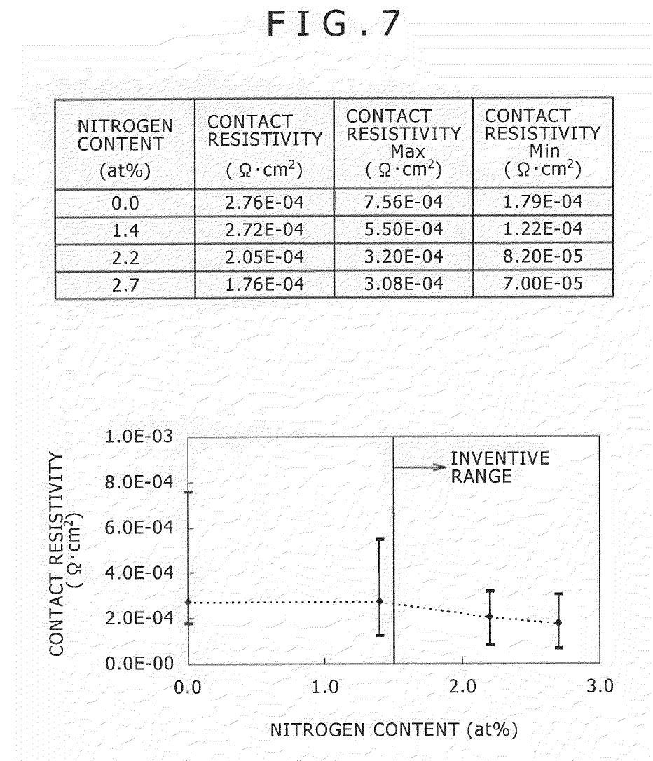

These results are shown in FIGS. 6 and 7.

Out of these, FIG. 6 is a diagram graphing the relationship between the gas flow rate ratio (F2/F1) and the contact resistivity based on data in the table in the upper part of FIG. 6.

Further, FIG. 7 is a diagram graphing the relationship between the nitrogen content in the ITO film containing nitrogen (ITO: N) and the contact resistivity based on data in the table in the upper part of FIG. 7. Herein, the nitrogen content is not an experimental value, but is indirectly determined from the gas flow rate ratio (F2/F1) based on the bend line of FIG. 8 showing the correlation between the gas flow rate ratio (F2/F1) and the nitrogen content. For FIG. 8, for simplification of the experiment, the present inventors previously performed the basic experiment so as to enable calculation of the nitrogen content based on the gas flow rate ratio (F2/F1), and thus examined the correlation of both.

From FIGS. 6 and 7, it is indicated as follows: as the ratio of nitrogen in the ITO: N film and the gas flow rate ratio expressed as the ratio of F2/F1 increases more than 0 by addition of a nitrogen gas into the inert gas, the mean value of the contact resistivity decreases, and the variance of the contact resistivity also tends to largely decrease. In FIG. 6, there are shown only the results when the gas flow rate ratio is up to 0.15. However, it has been experimentally confirmed that, when the upper limit of the gas flow rate ratio falls within the range of 0.5, the same tendency as described above is obtained. Similarly, in FIG. 7, there are shown only the results when the nitrogen content in the ITO: N film is up to 3.5 at %. However, it has been experimentally confirmed that, when the upper limit of the nitrogen content in the ITO: N film falls within the range of 5 at %, the same tendency as described above is obtained.

### Example 2

In this example, there were examined the mean value and the variance of the contact resistivities when various aluminum alloy films shown in Table 1 were used. Specifically, the contact resistivities were examined in the same manner as in Example 1, except that an IZO film was used as the transparent conductive film, and the gas flow rate ratios (F2/F1) were set at 0 and 0.1 in Example 1. All of the aluminum alloy films shown in Table 1 are preferably used as the materials for direct contact.

These results are described together in Table 1. Herein, the nitrogen contents in the IZO film containing nitrogen (first transparent conductive film, IZO: N) when the gas flow rate ratios (F2/F1)=0 and 0.1 are 0 at % and 2.3 at %, respectively.

TABLE 1

| | | Gas flow rate | | Gas flow rate | |
|---|---|---|---|---|---|
| | | ratio = 0 | | ratio = 0.1 | |
| | | Contact | | Contact | |
| | Composition of Al alloy | resistivity | Variance | resistivity | Variance |
| No. | film | (Ω · cm²) | (Ω · cm²) | (Ω · cm²) | (Ω · cm²) |
| 1 | Al—0.3at % Ni—0.35at % La | 2.7E−04 | 6.E−04 | 2.1E−04 | 2.E−04 |
| 2 | Al—0.3at % Ni—0.35at % Dy | 3.5E−04 | 8.E−04 | 2.7E−04 | 3.E−04 |
| 3 | Al—0.3at % Ni—0.35at % Gd | 3.0E−04 | 7.E−04 | 2.3E−04 | 2.E−04 |
| 4 | Al—0.3at % Ni—0.35at % Nd | 2.5E−04 | 6.E−04 | 1.9E−04 | 3.E−04 |
| 5 | Al—0.3at % Ni—0.35at % Y | 3.0E−04 | 7.E−04 | 2.3E−04 | 3.E−04 |
| 6 | Al—0.3at % Ni—0.35at % Co | 2.8E−04 | 5.E−04 | 2.2E−04 | 2.E−04 |
| 7 | Al—0.3at % Ni—0.35at % Mg | 2.9E−04 | 6.E−04 | 2.3E−04 | 2.E−04 |
| 8 | Al—0.3at % Ni—0.35at % Fe | 3.0E−04 | 6.E−04 | 2.3E−04 | 2.E−04 |
| 9 | Al—0.3at % Ni | 3.2E−04 | 6.E−04 | 2.5E−04 | 2.E−04 |
| 10 | Al—0.3at % Ag | 3.5E−06 | 5.E−04 | 2.7E−04 | 2.E−04 |
| 11 | Al—0.3at % Zn | 3.0E−06 | 6.E−04 | 2.3E−04 | 2.E−04 |
| 12 | Al—0.3at % Cu | 3.0E−06 | 6.E−04 | 2.3E−04 | 2.E−04 |
| 13 | Al—0.3at % Ge | 3.2E−06 | 7.E−04 | 2.5E−04 | 3.E−04 |

From Table 1, it has been indicated that the effects of the present invention are also exerted in other embodiments than Example 1. Specifically, it has been confirmed as follows. Even in the case where an IZO film is used as the transparent conductive film, and various aluminum alloys shown in Table 1 are used as the aluminum alloy films, when the flow rate ratio of a mixed gas containing a nitrogen gas is controlled within the range of the present invention to implement a transparent electrode of a lamination structure specified in the present invention, it is also possible to suppress the variance while keeping the low contact resistivity even when the aluminum alloy is in direct contact with the transparent electrode.

### Example 3

In this example, it will be verified that use of the transparent electrode of the present invention can provide a high light transmission characteristics substantially comparable to that when a conventional transparent conductive film is used. Specifically, there were measured the transmittances to a visible light (wavelength 480 nm, 550 nm, and 660 nm) upon formation of a lamination film of a first transparent conductive film (TCO-N) and a second transparent conductive film (TCO) in the following manner. Herein, using an ITO film as the transparent conductive film, the relationship between the ratio (T1/T2) of the thickness (T1) of the first transparent conductive film and the thickness (T2) of the second transparent conductive film and the transmittance was compared and studied. The sum of T1 and T2 was set at 50 nm (=constant).

First, on the same glass substrate as that in Example 1, an ITO film containing nitrogen (first transparent conductive film) was deposited with a sputtering process. Specifically, sputtering was carried out under the same sputtering conditions as those in Example 1, except that ITO was used as the target material, the gas flow rate ratio (F2/F1) was set at 0.125, and the deposition time was adjusted within the range of 5 to 25 seconds. Thus, a first transparent conductive film with a thickness T1 of 10 to 50 nm was deposited.

Then, sputtering was carried out under the same sputtering conditions as those in Example 1, except that all the gases in the sputtering device were replaced with an Ar gas, and the deposition time was adjusted within the range of 5 to 25 seconds. Thus, a second transparent conductive film with a thickness T2 of 0 to 50 nm was deposited.

In this example, those were evaluated as acceptable which satisfied the transmittance of 90% or more at any wavelength of 480 nm, 550 nm, and 660 nm (those having a reduction ratio of the transmittance within the range of 10% or less relative to the reference value) with reference to the transmittance at each wavelength when only the ITO film was deposited (T1=0, and hence T1/T2=0)

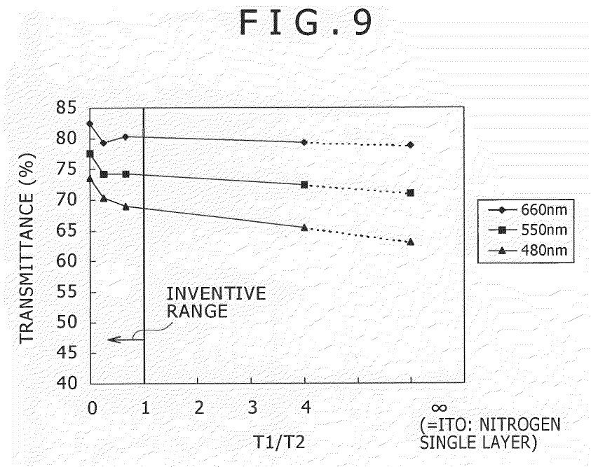

These results are shown in FIG. 9.

As shown in FIG. 9, when the ratio (T1/T2) of thicknesses of the first transparent conductive film and the second transparent conductive film was set at 1 or less, and the thickness (T1) of the first transparent conductive film was made equal to, or smaller than the thickness (T2) of the second transparent conductive film, a desirable high transmittance was obtained at every wavelength. In contrast, when the ratio of thicknesses (T1/T2) was more than 1, the transmittance largely decreased.

For example, when attention is focused on T1/T2=4, the transmittances at 660 nm and 550 nm satisfy the acceptability criteria as shown in the following (1) to (3). However, the transmittance at 480 nm did not satisfy the acceptability criteria, and hence it was finally evaluated as unacceptable.

(1) The transmittance at a wavelength of 660 nm is about 79%, and satisfies 90% (82%×0.9≈74%) or more of the transmittance (about 82%) upon deposition of only the ITO film;

(2) The transmittance at a wavelength of 550 nm is about 72%, and satisfies 90% (78%×0.9≈70%) or more of the transmittance (about 78%) upon deposition of only the ITO film; and

(3) The transmittance at a wavelength of 480 nm is about 65%, and satisfies 90% (73%×0.9≈66%) or more of the transmittance (about 73%) upon deposition of only the ITO film.

From this result, it has been confirmed that use of the transparent electrode including only the first transparent conductive film (i.e., including only the nitrogen-containing transparent conductive film) as in Patent Document 4 described above results in large reduction of the transmittance.

Incidentally, in this example, the results in the case of use of the ITO film are shown. However, it has been experimentally confirmed that, even when an IZO film is used in place of the ITO film, the same tendency as described above can be observed.

From the results of Examples 1 to 3, it has been verified that, use of the transparent electrode of the present invention can control the variance low while keeping the low contact resistivity, and can also ensure the high transmittance even in the case of direct contact with the aluminum alloy film.

The present invention was described in details by reference to specific embodiments. However, it is apparent to those skilled in the art that various changes and modifications may be made without departing from the spirit and scope of the present invention.

Incidentally, this application is based on Japanese Patent application (Japanese Patent Application No. 2007-051858) filed Mar. 1, 2007, the entire contents of which are hereby incorporated by reference.

Further, all references herein cited are entirely incorporated.

### INDUSTRIAL APPLICABILITY

In accordance with the present invention, there is provided a transparent electrode for a display device, having a low contact resistance with less variance and high transmittance even when the transparent electrode is in direct contact with the aluminum alloy film. Therefore, use of the transparent electrode for a display device of the present invention enables manufacturing of a high-performance display device with stability and good reproducibility.

1. A transparent electrode for a display device, comprising a first transparent conductive film comprising nitrogen, and a second transparent conductive film not containing nitrogen, the first transparent conductive film being in contact with an aluminum alloy film.

2. The transparent electrode for a display device according to claim 1, wherein the ratio of nitrogen contained in the first transparent conductive film is 1.5 at % or more and 5 at % or less.

3. The transparent electrode for a display device according to claim 1, wherein the thickness (T1) of the first transparent conductive film falls within the range of 1 nm or more and 25 nm or less.

4. The transparent electrode for a display device according to claim 1, wherein the ratio (T1/T2) of the thickness (T1) of the first transparent conductive film and the thickness (T2) of the second transparent conductive film is 1 or less.

5. The transparent electrode for a display device according to claim 1, wherein the aluminum alloy film comprises at least one element selected from the group consisting of Ni, Ag, Zn, Cu, and Ge as an alloy element in an amount within the range of 0.1 at % or more and 6 at % or less.

6. The transparent electrode for a display device according to claim 1, wherein the aluminum alloy film comprises at least one element selected from the group consisting of Ni, Ag, Zn, Cu, and Ge as an alloy element in an amount within the range of 0.1 at % or more and 2 at % or less.

7. The transparent electrode for a display device according to claim 1, wherein the aluminum alloy film further comprises at least one element selected from the group consisting of La, Gd, Dy, Mg, Nd, Y, Fe, and Co as an alloy element in an amount within the range of 0.1 at % or more and 2 at % or less.

8. The transparent electrode for a display device according to claim 1, wherein the aluminum alloy film is for use in source-drain electrodes or a reflection electrode.

9. A display device comprising the transparent electrode for a display device according to claim 1.

10. A method for manufacturing the transparent electrode for a display device according to claim 1, comprising:
1) depositing a first transparent conductive film comprising nitrogen on an aluminum alloy film with a sputtering process; and
2) depositing a second transparent conductive film not containing nitrogen on the first transparent conductive film comprising nitrogen with a sputtering process;
wherein said 1) is performed by using a mixed gas of an inert gas and a nitrogen gas, and controlling the ratio (F2/F1) of the flow rate F2 of a nitrogen gas to the flow rate F1 of the mixed gas within the range of 0.05 or more and 0.5 or less.
